(19) United States
(12) Patent Application Publication
(10) Pub. No.: US 2009/0116275 A1
(43) Pub. Date: May 7, 2009

(54) CONVENTIONALLY PRINTABLE NON-VOLATILE PASSIVE MEMORY ELEMENT AND METHOD OF MAKING THEREOF

(76) Inventors: Leenders Luc, Herentals (BE); Michel Werts, Landgraaf (NL)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(21) Appl. No.: 12/298,684

(22) PCT Filed: Mar. 22, 2007
(86) PCT No.: PCT/EP07/52724

§ 371 Date: Oct. 27, 2008

(30) Foreign Application Priority Data
Apr. 28, 2006 (EP) 06113267.6

(51) Int. Cl. G11C 17/10; H01L 21/02

(52) U.S. Cl. 365/103; 438/381; 257/E21.52; 257/786

(57) ABSTRACT

A non-volatile passive memory element comprising on a single surface a first electrode system and a second electrode system together with an insulating system, unless the insulating system is the surface, wherein the first electrode system is insulated from the second electrode system, the first and the second electrode systems are pattern systems and at least one conductive or semi-conducting bridge is present between the first and second electrode systems, and wherein the non-volatile passive memory device is exclusive of metallic silicon and the systems and the conductive or semiconducting bridges are printable using conventional printing processes with the optional exception of the insulating system if the insulating system is the surface. A non-volatile passive memory device comprising a support and on at least one side of the support the above-mentioned non-volatile passive memory element. A process for providing the above-mentioned non-volatile passive memory device, comprising the realization on a single surface of the support of the steps of: providing a first electrode system pattern, optionally providing an insulating pattern, providing a second electrode system pattern, and providing at least one conductive or semiconducting bridge between the first electrode system pattern and the second electrode system pattern at predesignated points, wherein at least one of the steps is realized with a conventional printing process and two of said steps are optionally performed simultaneously.

### FIELD OF THE INVENTION

The present invention concerns a conventionally printable non-volatile passive memory element, a conventionally printable non-volatile memory device precursor, a conventionally printable non-volatile memory device and methods of making a conventionally printable non-volatile memory device.

### BACKGROUND OF THE INVENTION

There is currently an increasing demand for disposable, inexpensive, flexible, passive memory device-containing tags and labels in which information is stored, for example as anti-counterfeiting tags in packaging. Production of such non-volatile memory elements, including writing of the information, should be easy and inexpensive and preferably should be capable of being incorporated in the tag, label and package printing process or in the packaging process itself and should consist of uncomplicated and inexpensive materials and involve a minimum of processing steps. For use in packages, it is important that the memory device is relatively robust and fairly insensitive to mechanical shock, temperature changes and other environmental influences.

Conventional silicon-based semiconductor memories have the disadvantage of requiring expensive and complex processing, the high process temperatures and the non-flexibility making them unsuitable for use on packaging substrates. Moreover, silicon-based semiconductor memories pose considerable environmental issues upon disposal. U.S. Pat. No. 6,542,397 discloses an apparatus comprising: at least one designated memory cell of a plurality of memory cells, each designated memory cell having a resistance-altering constituent disposed therein, but only exemplifies silicon-based read-only resistor memories. U.S. Pat. No. 6,649,499 discloses a method of making a memory comprising: diffusing of a resistance-altering constituent into a plurality of memory cells, the plurality of memory cells comprising polycrystalline silicon and the resistance-altering constituent comprising at least one Group IA element; and moving at least a portion of an implanted dose of the resistance-altering constituent from the conductive layer of at least one memory cell. In these resistor memories, information is stored by alteration of the resistance at pre-selected crossing points. Crosstalk between adjacent word lines are reduced when the resistance in each memory cell is significantly higher than the resistance of the bit lines and word lines. However, this does not prevent the existence of alternative current paths.

U.S. Pat. No. 6,107,666 discloses a high density ROM device, comprising: a substrate; and at least one memory array, including: a first insulating layer located over a surface of the substrate, plural bit lines located over the first insulating layer and extending in a first direction, said bit lines being spaced from one another at essentially equal intervals; a second insulating layer formed over the plural bit lines, at least one via formed in the second insulating layer and exposing a portion of the bit lines, and plural word lines located over the second insulating layer and extending in a second direction that crosses the first direction to form an angle, said word lines being spaced from one another at essentially equal intervals; and wherein some of the word lines are connected to the bit lines using the via and some of the word lines are isolated from the bit lines using the second insulating layer. U.S. Pat. No. 6,107,666 discloses a read only memory device in which metal bit lines and word lines are present. Electrical interconnects are made by the application of a metal in pre-selected vias present between the bit lines and word lines.

However, the production processes for the resistor memory cells disclosed in U.S. Pat. No. 6,107,666, U.S. Pat. No. 6,542,397 and U.S. Pat. No. 6,649,499 all rely on evaporation and etching methods to apply the metal or silicon structures, requiring high temperatures in the range of 300° C. to 400° C., which results in melting or severe degradation of polymer-based or paper-based substrates, hence making it unsuitable for packaging. Therefore such metal or silicon structures neither lend themselves to incorporation into tag, label and package printing process or into the packaging process nor do they lend themselves to environmentally friendly disposal.

Information can be stored electrically in a WORM memory by using the anti-fuse principle. U.S. Pat. No. 6,656,763, for example, discloses a method of making an organic memory cell comprising: providing a first electrode; forming a passive layer comprising a conductivity facilitating compound over the first electrode; forming an organic semiconductor layer over the passive layer using a spin-on technique, the spin-on technique comprising applying a mixture of i) at least one of a conjugated organic polymer, a conjugated organometallic compound, a conjugated organometallic polymer, a buckyball, and a carbon nanotube and ii) at least one solvent selected from the group consisting of glycol ether esters, glycol ethers, furans, and alkyl alcohols containing from about 4 to about 7 carbon atoms; and providing a second electrode over the organic semiconductor layer.

Furthermore, US 2004/0149552A1 discloses an electronic switch comprising: a first conductor; a second conductor; and a conductive organic polymer layer in contact with, and lying between, the first conductor and the second conductor, the conductive organic polymer layer in one of a first state in which the organic polymer layer conducts current between the first conductor and the second conductor with relatively high conductivity, and a second state, in which the organic polymer layer conducts current between the first conductor and the second conductor with relatively lower conductivity. The resistance of a semiconductor layer present between word lines and bit lines can be electrically altered by applying a ‘high’ voltage pulse, thereby increasing the resistance. To prevent alternative current paths it is necessary to include additional layers between the word lines and bit lines in each memory cell to form diodes, hereby making the manufacturing process more complicated.

The printing of memories has been proposed in the art for several different types of devices. US 2003/0230746A1 discloses a memory device comprising: a first semiconducting polymer film having a first side and a second side, wherein said first semiconducting polymer film includes an organic dopant; a first plurality of electrical conductors substantially parallel to each other coupled to said first side of said first semiconducting polymer layer; and a second plurality of electrical conductors substantially parallel to each other, coupled to said second side of said first semiconducting polymer layer and substantially mutually orthogonal to said first plurality of electrical conductors, wherein an electrical charge is localized on said organic dopant. The structures of the doped semiconducting film, layered between two conducting line patterns are simple. However, these memories are volatile, and the information is lost if no power is applied.

WO 02/0029706A1 discloses an electronic bar code comprising: a bar code circuit that stores a code that is electronically readable, wherein the code is defined by a polymer printing process; and an interface coupled to the bar code circuit to allow a bar code reader to access the code stored in the bar code circuit. The printed electronic circuit consists of a number of electronic components of which the presence or absence of the component or its connection determines the stored information.

U.S. Pat. No. 5,464,989 discloses a mask ROM having a plurality of memory cells, comprising: a semiconductor substrate having a main surface; a plurality of parallel first signal lines extending in a column direction on said main surface of said semiconductor substrate, a plurality of parallel second signal lines extending in a row direction on said main surface of said semiconductor substrate, crossing said plurality of first signal lines at a plurality of crossovers each forming a respective memory cell of said plurality of memory cells; an insulation film formed between said plurality of first signal lines and said plurality of second signal lines; and selecting means for selecting one of said plurality of first signal lines and one of said plurality of second signal lines and causing electric field between the selected first signal line and the selected second signal line by applying potential difference between the selected first signal line and the selected second signal line, said insulation film having, at each of said plurality of crossovers for storing data, one of i) a first thickness necessary for keeping an insulating state between the selected first signal line and the selected second signal line even if an electric field is received between the first signal line selected by the selecting means and the second signal line selected by the selecting means, ii) a second thickness for causing a first tunnel current to flow between the selected first signal line and the selected second signal line when the electric field is received between the first signal line and the second signal line selected by the selecting means, and iii) a third thickness for causing a second tunnel current to flow between the selected first signal line and the selected second signal line when the electric field is received between the first signal line and the second signal line selected by the selecting means. The production of a passive matrix ROM is thereby disclosed in U.S. Pat. No. 5,464,989 based on conductive electrodes, separated by an isolating oxide film in which a tunnel phenomenon is generated with storage of multiple bit levels in one memory cell. Variations in the oxide layer thickness leads to different tunnel currents through the layer, which encode for multiple levels in the information in each cell.

WO 02/079316A discloses an aqueous composition containing a polymer or copolymer of a 3,4-dialkoxythiophene in which the two alkoxy groups may be the same or different or together represent an optionally substituted oxy-alkylene-oxy bridge, a polyanion and a non-Newtonian binder; a method for preparing a conductive layer comprising: applying the above-described aqueous composition to an optionally subbed support, a dielectric layer, a phosphor layer or an optionally transparent conductive coating; and drying the thereby applied aqueous composition; antistatic and electroconductive coatings prepared according to the above-described method for preparing a conductive layer; a printing ink or paste comprising the above-described aqueous composition; and a printing process comprising: providing the above-described printing ink; printing the printing ink on an optionally subbed support, a dielectric layer, a phosphor layer or an optionally transparent conductive coating.

However, WO 02/079316A only discloses the application of such inks for applying antistatic or electroconductive layers to an optionally subbed support, a dielectric layer, a phosphor layer or an optionally transparent conductive layer, which may be a step in the production of electroluminescent devices which can be used in lamps, displays, back-lights e.g. LCD, automobile dashboard and keyswitch backlighting, emergency lighting, cellular phones, personal digital assistants, home electronics, indicator lamps and other applications in which light emission is required.

WO 03/000765A discloses a non-dye containing flexographic ink containing a polymer or copolymer of a 3,4-dialkoxythiophene in which the two alkoxy groups may be the same or different or together represent an optionally substituted oxy-alkylene-oxy bridge, a polyanion and a latex binder in a solvent or aqueous medium, characterized in that the polymer or copolymer of a 3,4-dialkoxythiophene is present in a concentration of at least 0.1% by weight in the ink and that the ink is capable of producing a calorimetrically additive transparent print; a method of preparing the flexographic ink; and a flexographic printing process therewith. However, WO 03/000765A only indicates the application of such inks for applying antistatic and electroconductive patterns to an optionally subbed support, a dielectric layer, a phosphor layer and a transparent conductive layer, which may be a step in the production of electrical circuitry for single and limited use items such as toys, in capacitive antennae as part of radiofrequency tags, in electroluminescent devices which can be used in lamps, displays, back-lights e.g. LCD, automobile dashboard and keyswitch back-lighting, emergency lighting, cellular phones, personal digital assistants, home electronics, indicator lamps and other applications in which light emission is required.

WO 2006/045764A discloses a passive memory element comprising a first electrode system, an insulating system and a second electrode system, wherein said first electrode system is a pattern system; wherein said first electrode is insulated from said second electrode system; wherein at least one conductive bridge is present between said first and said second electrode systems; and wherein said systems and said conductive bridges are printable using conventional printing processes.

There is therefore a need for an easy and inexpensive means of storing information which can be easily incorporated in a tag, label or package printing process or the packaging process itself.

Moreover, such easy and inexpensive means of storing information must be capable of lending itself to environmentally friendly disposal.

### PRIOR ART

Heretofore, the following prior art documents are known to the applicant:

GB 1 131 526A published on Oct. 23, 1968

GB 1 260 045A published on Jan. 12, 1972

U.S. Pat. No. 5,464,989 published on Nov. 7, 1995

U.S. Pat. No. 6,084,796 published on Jul. 4, 2000

U.S. Pat. No. 6,107,666 published on Aug. 22, 2000

U.S. Pat. No. 6,542,397 published on Apr. 1, 2003

U.S. Pat. No. 6,649,499 published on Nov. 18, 2003

U.S. Pat. No. 6,656,763 published on Dec. 2, 2003

US 2003/0230746A1 published on Dec. 18, 2003

US 2004/0149552A1 published on Aug. 5, 2004

WO 02/029706A1 published on Apr. 11, 2002

WO 02/071505A1 published on Sep. 22, 2002

WO 02/079316A1 published on Oct. 10, 2002

WO 03/000765A1 published on Jan. 3, 2003

WO 2006/045764A published on May 4, 2006

### ASPECTS OF THE INVENTION

It is therefore an aspect of the present invention to provide inexpensive non-volatile memory elements.

It is therefore a further aspect of the present invention to realize an easy and inexpensive means of storing information which can be easily incorporated in a tag, label or package printing process or the packaging process itself.

It is a further aspect of the present invention to realize an easy and inexpensive means of storing information which is capable of lending itself to environmentally friendly disposal.

Further aspects and advantages of the invention will become apparent from the description hereinafter.

### SUMMARY OF THE INVENTION

It has been surprisingly found that an element comprising a first patterned electrode system, a second patterned electrode system, an insulating system between the first patterned electrode system and the second patterned electrode system and at least one conductive or semiconducting bridge between the first patterned electrode system and the second patterned electrode system, wherein in the absence of the at least one conductive or semiconducting bridge there is no direct electrical contact between the first and the second electrode systems is printable by conventional printing processes.

Aspects of the present invention are realized by a non-volatile passive memory element comprising on a single surface a first electrode system and a second electrode system together with an insulating system, unless the insulating system is the surface, wherein the first electrode system is insulated from the second electrode system, the first and the second electrode systems are pattern systems and at least one conductive or semiconducting bridge is present between the first and second electrode systems, and wherein the non-volatile passive memory device is exclusive of metallic silicon and the systems and the conductive or semiconducting bridges are printable using conventional printing processes with the optional exception of the insulating system if the insulating system is the surface.

Aspects of the present invention are also realized by a non-volatile passive memory device comprising a support and on at least one side of the support a non-volatile passive memory element, the non-volatile passive memory element comprising on a single surface of the support a first electrode system and a second electrode system together with an insulating system, unless the insulating system is the surface, wherein the first electrode system is insulated from the second electrode system, the first and the second electrode systems are pattern systems and at least one conductive or semiconducting bridge is present between the first and second electrode systems, and wherein the non-volatile passive memory device is exclusive of metallic silicon and the systems and the conductive or semiconducting bridges are printable using conventional printing processes with the optional exception of the insulating system if the insulating system is the surface. Aspects of the present invention have also been realized by a process for providing the above-mentioned non-volatile passive memory device, comprising the realization on a single surface of the support the steps of: providing a first electrode system pattern, optionally providing an insulating pattern, providing a second electrode system pattern, and providing at least one conductive or semiconducting bridge between the first electrode system pattern and the second electrode system pattern at predesignated points, wherein at least one of the steps is realized with a conventional printing process and two of the steps are optionally performed simultaneously.

Aspects of the present invention are also realized by a non-volatile passive memory device precursor comprising a support and on at least one side of the support a non-volatile passive memory element precursor, the non-volatile passive memory element precursor comprising on a single surface of the support a first electrode system and a second electrode system together with an insulating system, unless the insulating system is the surface, wherein the first electrode system is insulated from the second electrode system, the first and the second electrode systems are pattern systems and wherein the non-volatile passive memory device is exclusive of metallic silicon and the systems are printable using conventional printing processes with the optional exception of the insulating system if the insulating system is the surface.

Aspects of the present invention have also been realized by a process for providing a non-volatile passive memory device from a passive device memory precursor comprising a support and on at least one side of the support a non-volatile passive memory element precursor, the non-volatile passive memory element precursor comprising on a single surface of the support a first electrode system and a second electrode system together with an insulating system, unless the insulating system is the surface, wherein the first electrode system is insulated from the second electrode system, the first and the second electrode systems are pattern systems and wherein the non-volatile passive memory device is exclusive of metallic silicon and the systems are printable using conventional printing processes with the optional exception of the insulating system if the insulating system is the surface, the process comprising the step of providing at least one conductive or semiconducting bridge between the first electrode pattern and the second electrode pattern at predesignated points.

Preferred embodiments of the present invention are disclosed in the detailed description of the invention.

### BRIEF DESCRIPTION OF THE FIGURES

FIG. 1 illustrates embodiments of a one dimensional memory device.

### DETAILED DESCRIPTION OF THE INVENTION

### Definitions

The term “support”, as used in disclosing the present invention, means a “self-supporting material” so as to distinguish it from a “layer” which may be coated on a support, but which is itself not self-supporting, and includes the insulating surface or surfaces on which the non-volatile passive memory element or elements are realized even if this insulating surface or these insulating surfaces are provided by a coated or conventionally printed layer. The term printable, as used in disclosing the present invention, means capable of being printed by conventional impact and/or non-impact printing processes and excludes processes such as evaporation, etching, diffusion processes used in the production of conventional electronics e.g. silicon-based electronics.

The term conventional printing processes, as used in disclosing the present invention, includes but is not restricted to ink-jet printing, intaglio printing, screen printing, flexographic printing, offset printing, stamp printing, gravure printing and thermal and laser-induced processes.

The term conductive or semiconducting bridge, as used in disclosing the present invention, means a conductive blob having any shape providing an instantaneous electrical contact between the second electrode pattern system and the first electrode pattern system on an insulating surface; or providing an instantaneous electrical contact with the first electrode pattern and instantaneous electrical contact with the second electrode pattern upon realization thereof; or being an integral part of the second electrode pattern system providing an instantaneous electrical contact with the first electrode pattern system on an insulating surface; or being an integral part of the first electrode pattern system providing instantaneous electrical contact with the second electrode pattern upon realization thereof.

The term pattern, as used in disclosing the present invention, means a non-continuous layer which can be in any form of lines, squares, circles or any random configuration.

The term layer, as used in disclosing the present invention, means a coating covering the whole area of the entity referred to e.g. a support.

The term metallized support, as used in disclosing the present invention, means a support at least one surface of which is covered with metal by any process known to one skilled in the art e.g. lamination, attachment of metal foil, sputtering and evaporation. The term insulator, as used in disclosing the present invention, means a material providing a leak current between two electrodes of <5 μA measured at a voltage of 5V.

The term conductive is related to the electric resistance of the material, the electric resistance of a layer being generally expressed in terms of surface resistance Rₛ (unit Ω; often specified as Ω/square). Alternatively, the conductivity may be expressed in terms of the specific (volume) resistivity Rᵥ=Rₛ·d, wherein d is the thickness of the layer, and Rᵥ or ρ is in units of ohm-cm. The term conductive, as used in disclosing the present invention, means a material having a surface resistance of <10⁶ ohm/square, preferably <10⁴ ohm/square or having a specific resistivity of <10² ohm-cm, preferably <1 ohm-cm.

The term crosstalk, as used in disclosing the present invention, means a misinterpretation of a bit attributed to the influence of other bits stored in the non-volatile passive memory device of the present invention resulting from the influence of the wire resistance of each bit line.

The term intrinsically conductive polymer, as used in disclosing the present invention, means organic polymers which have (poly)-conjugated π-electron systems (e.g. double bonds, aromatic or heteroaromatic rings or triple bonds) and whose conductive properties are not influenced by environmental factors such as relative humidity.

The term transparent, as used in disclosing the present invention, means having the property of transmitting at least 70% of the incident light without diffusing it.

The term opaque, as used in disclosing the present invention, means the property of rendering invisible structures otherwise visible to the human eye via transmitted or reflected light in the visible spectrum (400 to 700 nm).

The term flexible, as used in disclosing the present invention, means capable of following the curvature of a curved object such as a drum e.g. without being damaged.

The term “substantially parallel with the surface”, as used in disclosing the present invention, means substantially equidistant from the surface in a direction perpendicular to the surface.

The term porous, as use in disclosing the present invention, means containing many minute channels and minute open spaces.

PEDOT, as used in disclosing the present invention, represents poly(3,4-ethylenedioxythiophene).

PSS, as used in disclosing the present invention, represents poly(styrene sulfonic acid) or poly(styrene sulfonate).

PANI, as used in disclosing the present invention, represents polyaniline.

### Non-Volatile Passive Memory Element

Aspects of the present invention are realized by a non-volatile passive memory element comprising on a single surface a first electrode system and a second electrode system together with an insulating system, unless the insulating system is the surface, wherein the first electrode system is insulated from the second electrode system, the first and the second electrode systems are pattern systems and at least one conductive or semiconducting bridge is present between the first and second electrode systems, and wherein the non-volatile passive memory device is exclusive of metallic silicon and the systems and the conductive or semiconducting bridges are printable using conventional printing processes with the optional exception of the insulating system if the insulating system is the surface. The conductive or semiconducting bridges are substantially parallel with the surface. The non-volatile passive memory element, according to the present invention, may have any form i.e. be planar or non-planar. According to a first embodiment of the non-volatile passive memory element, according to the present invention, the surface is a non-metallic surface.

According to a second embodiment of the non-volatile passive memory element, according to the present invention, the non-volatile passive memory element comprises a series of interrupted conducting or semiconducting lines bridged by at least one conductive or semiconducting bridge.

### Non-Volatile Passive Memory Device Precursor

Aspects of the present invention are also realized by a non-volatile passive memory device precursor comprising a support and on at least one side of the support a non-volatile passive memory element precursor, the non-volatile passive memory element precursor comprising on a single surface of the support a first electrode system and a second electrode system together with an insulating system, unless the insulating system is the surface, wherein the first electrode system is insulated from the second electrode system, the first and the second electrode systems are pattern systems and wherein the non-volatile passive memory device is exclusive of metallic silicon and the systems are printable using conventional printing processes with the optional exception of the insulating system if the insulating system is the surface. The non-volatile passive memory device precursor, according to the present invention, may have any form i.e. be planar or non-planar.

According to a first embodiment of the non-volatile passive memory device precursor, according to the present invention, the non-volatile passive memory element precursor is coated or conventionally printed with a porous insulating layer. This porous insulating layer enables conductive ink to penetrate through the porous insulating layer to the non-volatile passive memory element. All the layers in the non-volatile passive memory device precursor, bit lines, insulating pattern system, word lines and ‘conductive or semiconducting bridges’, can be applied by conventional printing processes including but not restricted to ink-jet printing, intaglio printing, screen printing, flexographic printing, offset printing, stamp printing, gravure printing and thermal and laser-induced processes. Either one conventional printing process can be used for all the layers in the non-volatile passive memory device precursor, or a combination of two or more conventional printing processes can be used.

### Non-Volatile Passive Memory Device-Configuration

Aspects of the present invention are realized by a non-volatile passive memory device comprising a support and on at least one side of the support a non-volatile passive memory element, the non-volatile passive memory element comprising on a single surface of the support a first electrode system and a second electrode system together with an insulating system, unless the insulating system is the surface, wherein the first electrode system is insulated from the second electrode system, the first and the second electrode systems are pattern systems and at least one conductive or semiconducting bridge is present between the first and second electrode systems, and wherein the non-volatile passive memory device is exclusive of metallic silicon and the systems and the conductive or semiconducting bridges are printable using conventional printing processes with the optional exception of the insulating system if the insulating system is the surface. The conductive or semiconducting bridges are substantially parallel with the surface. The non-volatile passive memory device, according to the present invention, may have any form i.e. be planar or non-planar.

According to a first embodiment of the non-volatile passive memory device, according to the present invention, the non-volatile passive memory element comprises a series of interrupted conducting or semiconducting lines bridged by at least one conductive or semiconducting bridge.

According to a second embodiment of the non-volatile passive memory device, according to the present invention, the support is a non-metallic or non-metallized support.

According to a third embodiment of the non-volatile passive memory device, according to the present invention, the support can be a flexible or rigid plastic, glass, paper, board, carton or a composite material of any of these materials optionally with a coated or conventionally printed layer on one or both surfaces. The support can also be metallic or a laminate of metal with plastic, paper or carton with an insulating surface or surfaces on which non-volatile passive memory elements are realized.

According to a fourth embodiment of the non-volatile passive memory device, according to the present invention, at least one of the first and second patterned electrode systems and the at least one conductive or semiconducting bridge comprises an inorganic conducting medium, e.g. a metal, a semiconducting metal oxide and carbon, or an organic conducting medium, e.g. an intrinsically conductive organic polymer.

According to a fifth embodiment of the non-volatile passive memory device, according to the present invention, the first electrode system and the second electrode system is a conducting or semiconducting material, which can be applied by a conventional printing process. Suitable conductive and semiconductive materials include conductive inks based on conductive metals (e.g. silver paste), conductive metal alloys, conductive metal oxides, semiconductive metal oxides and intrinsically conductive organic polymers (e.g. polyaniline, PEDOT), carbon black. Conductive inks based on intrinsically conductive organic polymers are preferred with inks based on PEDOT:PSS being particularly preferred due to its low absorption of visible light.

According to a sixth embodiment of the non-volatile passive memory device, according to the present invention, at least one of the first and second patterned electrode systems and the at least one conductive or semiconducting bridge comprises carbon.

According to a seventh embodiment of the non-volatile passive memory device, according to the present invention, at least one of the first and second patterned electrode systems and the at least one conductive or semiconducting bridge comprises a metal e.g. silver or gold.

According to an eighth embodiment of the non-volatile passive memory device, according to the present invention, the at least one conductive or semiconducting bridge is a conducting or semiconducting material, which can be applied by a conventional printing process. Suitable conductive and semiconductive materials include conductive inks based on conductive metals (e.g. silver paste), conductive metal alloys, conductive metal oxides, semiconductive metal oxides and intrinsically conductive organic polymers (e.g. polyaniline, PEDOT), carbon black. Conductive inks based on intrinsically conductive organic polymers are preferred with inks based on PEDOT:PSS being particularly preferred due to its low absorption of visible light.

According to a ninth embodiment of the non-volatile passive memory device, according to the present invention, at least one of the first and second patterned electrode systems and the at least one conductive or semiconducting bridge comprises a semiconducting metal oxide or doped metal oxide e.g. vanadium pentoxide, indium tin oxide or a metal antimonate.

According to a tenth embodiment of the non-volatile passive memory device, according to the present invention, at least one of the first and second patterned electrode systems and the at least one conductive or semiconducting bridge comprises an organic conducting medium, which is an intrinsically conductive organic polymer.

According to an eleventh embodiment of the non-volatile passive memory device, according to the present invention, at least one of the first and second patterned electrode systems and the at least one conductive or semiconducting bridge comprises a polythiophene, a polyaniline or a polypyrrole.

According to a twelfth embodiment of the non-volatile passive memory device, according to the present invention, at least one of the first and second patterned electrode systems and the at least one conductive or semiconducting bridge comprises a poly(3,4-alkylenedioxythiophene).

According to a thirteenth embodiment of the non-volatile passive memory device, according to the present invention, at least one of the first and second patterned electrode systems and the at least one conductive or semiconducting bridge comprises poly(3,4-ethylenedioxythiophene).

According to a fourteenth embodiment of the non-volatile passive memory device, according to the present invention, at least one of the first patterned electrode system, the second patterned electrode system, the insulating system and the at least one conductive or semiconducting bridge is transparent.

According to a fifteenth embodiment of the non-volatile passive memory device, according to the present invention, the non-volatile passive memory device is transparent, thereby becoming almost invisible to the unaided eye. This can be realized by using for example PEDOT:PSS as the conductive material for the electrodes and ‘conductive or semiconducting bridges’, and by using a transparent isolating material, for example a UV-curable ink. The physical or chemical structure of the marking would then be such that it does not reflect light in wavelengths in the visible spectrum (400 to 700 nm), so that the marking cannot be detected by the human eye i.e. would be invisible when viewed externally.

According to a sixteenth embodiment of the non-volatile passive memory device, according to the present invention, the ‘conductive or semiconducting bridges’ are colored, for example black by using a carbon black-based ink.

According to a seventeenth embodiment of the non-volatile passive memory device, according to the present invention, to visually hide the location of the ‘conductive or semiconducting bridges’, non-conducting black bridges may be conventionally printed between other points on the first and second electrode systems without conductive or semiconducting bridges. The conducting and non-conducting bridges may have any color, for example by adding dyes or pigments.

According to an eighteenth embodiment of the non-volatile passive memory device, according to the present invention, the memory device is overprinted by a conventional or non-conventional printing process with an image or homogeneously colored or opaque layer to visually hide the location of the ‘conductive or semiconducting bridges’ except for any electrical contacts required for reading out the stored information in contact. In this way data can be hidden/rendered invisible, which can be used to confirm, for example, authenticity or value, in paper documents, such as certificates, cards for collectors, advertisements, brochures, special-offer coupons, legal documents, and admission tickets. The image or homogeneously colored or opaque layer to visually hide the location of the “conductive or semiconducting bridges” may be removable by scratching with a coin or other sharp object.

According to a nineteenth embodiment of the non-volatile passive memory device, according to the present invention, a colored or opaque foil is laminated over the memory device to visually hide the location of the ‘conductive or semiconducting bridges’ except for any electrical contacts required for reading out the stored information in contact. Such lamination can also be realized by applying an adhesive sticker or label over the non-volatile passive memory element.

The conductivity of the electrodes and conductive or semiconducting bridges needs to be sufficient to have a current flowing through a conductive or semiconducting bridge that is significantly higher than the current measured through points on the first and second electrode systems without a conductive or semiconducting bridge. The resistance is preferably in the range of 1 to 100,000 Ohm per square and more preferably lower than 20,000 Ohm per square. The line width of the electrodes can be in the range from 5 to 1000 μm and more preferably from 100 to 500 μm. The line width of the isolating strips can be in the range from 10 to 10000 μm and more preferably from 100 to 5000 μm.

The position of the ‘conductive or semiconducting bridges’ in the non-volatile passive memory device may be different for each device, thus storing personalized/individual information, such as name, address, date of birth, etc or a products' manufacturing date/time and pricing.

According to a twentieth embodiment of the non-volatile passive memory device, according to the present invention, the non-volatile passive memory device may be combined with one or more security features e.g. security inks based on magnetic, infrared-absorbing, thermochromic, photochromic, coin-reactive, optically variable, fluorescent or phosphorescent compounds and the like, chemical or biological taggants based on isotopes, DNA, antibodies or specific detectable ingredients and the like can be included in one of the layers of the memory device. The non-volatile passive memory device may be overcoated or conventionally overprinted with a hologram, tamper proof security film, a barcode or the like. The non-volatile passive memory device, according to the present invention, may be conventionally printed on security paper.

According to a twenty-first embodiment of the non-volatile passive memory devices, according to the present invention, the number of conductive or semiconducting bridges is at least two.

### Non-Volatile Passive Memory Element-Operation

The present invention provides a non-volatile passive memory device comprising at least one simple non-volatile passive memory element, that is producible by conventional printing processes, in which information is stored by providing electrical interconnects (conductive or semiconducting bridges) between word lines and bit lines at predesignated points. Information is stored by the presence or absence of a conductive or semiconducting bridge between a word line and a bit line. By means of conventional printing of a conducting material between points on the first and second electrode systems, a conductive or semiconducting bridge is formed between a word line and a bit line. Readout of the data is accomplished by measuring the resistance between each bit line-word line combination. The resistivity can be read out electrically in contact or capacitively and corresponds to logical values in a binary code.

Such capacitive read out is a static or dynamic non-contact measurement performed at a short distance from the object concerned as exemplified in the method disclosed in U.S. Pat. No. 6,168,080, herein incorporated by reference, with a system as exemplified in U.S. Pat. No. 5,386,196, herein incorporated by reference, and using readers as exemplified in U.S. Pat. No. 6,168,080 and U.S. Pat. No. 6,202,929, herein incorporated by reference. U.S. Pat. No. 6,168,080 discloses a method of reading information encoded on a substrate behind a cover in a pattern using an electrically conducting ink comprising the steps of: relatively moving the encoded substrate and cover past a capacitance sensor in a fashion that permits different portions of the pattern to be measured at points of approximately equal proximity to the capacitance sensor; successively measuring the different portions of the pattern as the encoded substrate is relatively moved past the capacitance sensor: detecting variations in capacitance associated with the pattern of the conductive ink as a function of a relative position of the capacitance sensor along the covered substrate; and matching the detected variations in capacitance to stored information about similar patterns for reading the encoded information. The invention of U.S. Pat. No. 6,168,080 makes use of localized capacitance changes introduced onto a substrate by conductive or dielectric ink used to print encoded information such as a bar-code and variations in capacitance associated with the pattern of the conductive ink are detected as a function of the relative position of the capacitance sensor along the covered substrate and are compared to stored information about similar patterns for reading the encoded information. U.S. Pat. No. 6,202,929 discloses a reader for acquiring information encoded by a differentially conductive pattern comprising: a plurality of electrodes positioned within one or more electrical fields generated by at least one of the electrodes; a signal processor that obtains capacitive coupling measurements of the differentially conductive pattern between at least three different pairings of the electrodes as the differentially conductive pattern is relatively moved through the one or more electrical fields; and a logic processor that performs a first comparison between coupling measurements from at least two of the pairings to initiate a second comparison between coupling measurements involving other of the pairings to distinguish features within the differentially conductive pattern. The reader disclosed in U.S. Pat. No. 6,202,929 can include a plurality of electrodes positioned within one or more electrical fields generated by at least one of the electrodes, a signal processor obtaining capacitive coupling measurements of the differentially conductive pattern between at least three different pairings of the electrodes as the pattern is relatively moved through the one or more electrical fields with a logic processor comparing the simultaneous measurements with each other independently of variations having similar effects on the compared measurements to distinguish features of the differentially conductive pattern. U.S. Pat. No. 5,386,196 discloses a system for accurate contactless measurement of the resistivity of a material via capacitive coupling, comprising: a first induction transformer having a first primary coil and a first secondary coil, the first primary coil for receiving a periodic signal; a first transmission line stub connected to the first secondary coil; a transmission electrode connected to the first transmission line stub, the transmission electrode for capacitively coupling to a material when the material is disposed in close proximity to the transmission electrode; a reception electrode for capacitively coupling to the material when the material is capacitively coupled to the transmission electrode; a second transmission line stub connected to the reception electrode; and a second induction transformer having a second primary coil and a second secondary coil, the second primary coil being connected to the second transmission line stub, the second secondary coil for generating a resistivity signal indicative of the resistivity of the material.

Another aspect of the present invention relates to the retrieval of the covert information in the memory device by subsequent measurement of the resistance between the word lines and bit lines, wherein a low resistance, corresponding to an electrical conductive or semiconducting bridge, denotes one binary state and a high resistance, corresponding to points on the first and second electrode systems without an electrically conductive or semiconducting bridge, denotes a second binary state.

As may be recognized by those skilled in the art, no diode structures are present at the points on the first and second electrode systems, thereby allowing alternative current paths to be formed. In the non-volatile passive memory element, according to the present invention, a voltage is applied between one selected word line and one selected bit line. If no conductive or semiconducting bridge is present at the predesignated point between the selected word line and the selected bit line, no or a relatively small current will flow. However, if conductive or semiconducting bridges are present between predesignated points on the first and second electrode systems in the non-volatile passive memory element, the current may flow via an alternative pathway through three or more conductive or semiconducting bridges. This phenomenon is described for example in U.S. Pat. No. 6,055,180. Careful selection of the points on the first and second electrode systems at which a conductive or semiconducting bridge is created can prevent alternative current paths. This limits the amount of information stored but is acceptable for those applications where a low information content is sufficient. In the event that the resistance of the conductive or semiconducting bridges is significantly higher than the resistance of the bit lines and word lines, discrimination is possible between a ‘true’ conductive or semiconducting bridge and a false reading due to an alternative current path through three conductive or semiconducting bridges which will result in a smaller current.

### Process for Producing the Memory Passive Device

Aspects of the present invention have been realized by a process for providing a non-volatile passive memory device, the non-volatile passive memory device comprising a support and on at least one side of the support a non-volatile passive memory element, the non-volatile passive memory element comprising on a single surface of the support a first electrode system and a second electrode system together with an insulating system, unless the insulating system is the surface, wherein the first electrode system is insulated from the second electrode system, the first and the second electrode systems are pattern systems and at least one conductive or semiconducting bridge is present between the first and second electrode systems, and wherein the non-volatile passive memory device is exclusive of metallic silicon and the systems and the conductive or semiconducting bridges are printable using conventional printing processes with the optional exception of the insulating system if the insulating system is the surface, comprising the realization on a single surface of the support of the steps of: providing a first electrode system pattern, optionally providing an insulating pattern, providing a second electrode system pattern, and providing at least one conductive or semiconducting bridge between the first electrode system pattern and the second electrode system pattern at predesignated points, wherein at least one of the steps is realized with a conventional printing process and two of the steps are optionally performed simultaneously e.g. the provision of the first electrode system pattern and the second electrode system pattern, the provision of the first electrode system pattern and the at least one conductive or semiconducting bridge at predesignated points between the first and second electrode system patterns and, if the insulating system is the surface support, the provision of the first electrode system pattern and the at least one conductive or semiconducting bridge to the positions on the surface of the predesignated points on the yet to be coated second electrode system pattern.

If the insulating system is the surface of the support, that first electrode system pattern, the second electrode system pattern and the at least one conductive or semiconducting bridge between predesignated points between the first and second electrode system patterns can be provided simultaneously. The conductive or semiconducting bridges are substantially parallel with the surface. According to a first embodiment of the first process, according to the present invention, the provision of the second patterned electrode is realized in the same process step as the at least one conductive or semiconducting bridge between the first patterned electrode system and the second patterned electrode system e.g. directly between the second electrode pattern system and the first electrode pattern system through openings in the insulating pattern system or via a pre-existing conductive or semiconducting bridge to the first electrode pattern system or conductive or semiconducting bridges coprinted with the second electrode pattern system.

If the first electrode system, the second electrode system, the optional insulating system and the at least one conductive or semiconducting bridge are all provided in separate steps, the possible variations in the order in which the process steps are carried out are determined by whether or not the insulating system is the surface of the support. If the insulating system is the surface of the support, the first electrode system, the second electrode system and the at least one conductive or semiconducting bridge can be provided in any order, whereas if the insulating system is not the surface of the support, the first electrode system, the second electrode system and the insulating system can be provided in any order, but the at least one conductive or semiconducting bridge must be provided after these systems have been provided.

All the layers in the non-volatile passive memory device, bit lines, insulating pattern system, word lines and ‘conductive or semiconducting bridges’, can be applied by conventional printing processes including but not restricted to ink-jet printing, intaglio printing, screen printing, flexographic printing, offset printing, stamp printing, gravure printing and thermal and laser-induced processes. Either one conventional printing process can be used for all the layers in the non-volatile passive memory device, or a combination of two or more conventional printing processes can be used.

According to a second embodiment of the process, according to the present invention, at least one of the at least one conventional printing processes is a non-impact printing process e.g. ink-jet printing.

According to a third embodiment of the process, according to the present invention, at least one of the at least one conventional printing processes is an impact printing process e.g. offset printing, screen printing, flexographic printing, electrophotographic printing, electrographic printing, and stamp printing.

According to a fourth embodiment of the process, according to the present invention, the at least one conventional printing process is selected from the group consisting of ink-jet printing, intaglio printing, screen printing, flexographic printing, offset printing, stamp printing, gravure printing and thermal and laser-induced processes.

According to a fifth embodiment of the process, according to the present invention, the first electrode pattern, the optional insulating pattern, the second electrode pattern and the at least one conductive or semiconducting bridge are each performed by a conventional printing process which can be the same or different. According to a sixth embodiment of the process, according to the present invention, the first electrode pattern, the insulating pattern, the second electrode pattern and the at least one conductive or semiconducting bridge are performed by the same conventional printing process.

According to a seventh embodiment of the process, according to the present invention, the first electrode pattern, the insulating pattern, the second electrode pattern and the at least one conductive or semiconducting bridge are performed by ink-jet printing.

According to an eighth embodiment of the processes, according to the present invention, the first electrode pattern, the insulating pattern, the second electrode pattern and the at least one conductive or semiconducting bridge are performed by flexographic printing.

According to a ninth embodiment of the process, according to the present invention, the conductive or semiconducting bridge can be realized in the same process step as the first electrode pattern system or the second electrode pattern system.

According to a tenth embodiment of the process, according to the present invention, the step of storing the information by applying conductive or semiconducting bridges on predesignated points between the first electrode system pattern and the second electrode system pattern is performed in the same printing line as that providing the first electrode pattern system, the insulating pattern system and the second electrode pattern system.

According to an eleventh embodiment of the process, according to the present invention, the step of storing the information by applying conductive or semiconducting bridges on predesignated points between the first electrode pattern and the second electrode pattern is not performed in the same printing line as that providing the first electrode pattern, the insulating pattern and the second electrode pattern.

Printing according to the process, according to the present invention, can be carried out directly on a package, on a label, a ticket, an ID-card, a bank card, a legal document and banknotes. The memory device may act as an identification system, a security feature, an anti-counterfeiting feature, etc.

The non-volatile passive memory element, according to the present invention, can be produced in an inexpensive way by reel-to-reel printing. This conventional printing process consists of at least three steps, a) printing of the bit lines of a first electrode system on a substrate thereby realizing the first electrode system pattern, b) optionally printing of the lines of an insulating material thereby realizing the insulating system pattern, and c) printing of the word lines of a second electrode thereby realizing the second electrode system pattern, such that the two electrodes have no direct physical and electrical contact with one another. Information is then stored either by the separate conventional printing of a conducting material at predesignated points to form conductive or semiconducting bridges or the information is stored together with the printing of the first electrode system pattern, second electrode system pattern or insulating system pattern steps in the conventional printing of the non-volatile passive memory element.

Such an off-line step of storing the information by applying conductive or semiconducting bridges on predesignated points between the first electrode pattern and the second electrode pattern can be carried out by, for example, ink-jet printing, at the same or at a different location, at the same time or at a later time. This enables the personalization of each non-volatile passive memory element with different information.

According to a twelfth embodiment of the process, according to the present invention, at least the first electrode pattern, the optional insulating pattern and the second electrode pattern are realized by reel to reel printing.

The non-volatile passive memory element, according to the present invention, is producible by a conventional printing process.

Information can be stored by creating conductive or semiconducting bridges via a conventional printing process.

In another embodiment, information is stored in the memory device by a combination of two or more conventional printing steps, for example one part of the information is printed with the first electrode and a second part together with the second electrode, or one part of the information is printed together with the second electrode or the isolating layer and a second part is conventionally printed in a separate printing step in which additional ‘conductive or semiconducting bridges’ are printed. The first part of information might contain fixed information such as the name of a manufacturer, while the second part is variable, such as the production date or batch number.

According to a thirteenth embodiment of the process, according to the present invention, in a further step one or more of the at least one conductive or semiconducting bridges at predesignated points between the first electrode pattern and the second electrode pattern are rendered inoperative. This can be done in a chemical, thermal, electrical, mechanical or optical way. Since conductive or semiconducting bridges can be created and removed, the memory device then becomes rewritable.

According to a fourteenth embodiment of the process, according to the present invention, in a further step the non-volatile passive memory element is coated with an insulating layer except for any electrical contacts required for reading out the stored information in contact. According to a fifteenth embodiment of the process, according to the present invention, in a further step the non-volatile passive memory element is coated with an opaque insulating layer except for any electrical contacts required for reading out the stored information in contact. This opaque insulating layer may be porous or non-porous.

According to a sixteenth embodiment of the process, according to the present invention, in a further step the non-volatile passive memory element is coated with a transparent insulating layer except for any electrical contacts required for reading out the stored information in contact.

According to a seventeenth embodiment of the process, according to the present invention, in a further step the non-volatile passive memory element is coated with an opaque porous insulating layer. This opaque insulating layer may be rendered integrally or locally transparent in a further process step e.g. with a UV-curable lacquer.

According to an eighteenth embodiment of the process, according to the present invention, the support is a flexible support.

According to a nineteenth embodiment of the process, according to the present invention, the support is a flexible support and the non-volatile passive memory element is formed into a non-planar shape.

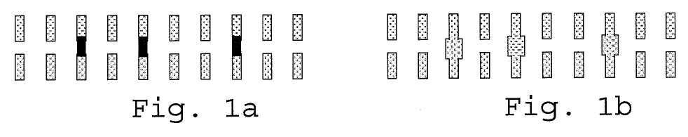

FIG. 1 shows a one dimensional memory device, consisting of a row of conducting or semiconducting lines that are all interrupted.

Information can be stored by conventionally printing a ‘pixel’ to electrically connect the two parts of the line, bridging the interruption (FIG. 1a). In case the stored information is the same for each printed memory device, the ‘conductive or semiconducting bridges’ information can be conventionally printed together with the lines in one printing step (FIG. 1b). Alternatively, in a row of continuous lines, a number of pre-selected lines can be made non-conducting by removal of deactivation of a part of the line. Readout of the data is achieved by measurement of the resistance over each line.

In a further embodiment of the non-volatile passive memory device, according to the present invention, the conductivity of the conductive or semiconducting bridges can be selected to be significantly lower than the conductivity of the electrode lines. One can distinguish between a ‘true’ conductive or semiconducting bridge and a measured conductive or semiconducting bridge due to alternative current paths. Since the current that flows via an alternative current path through three conductive or semiconducting bridges (resistances) instead of one, a difference in current can be detected. The conductivity of the electrode lines needs to be significantly higher to diminish additional resistances in the electrode lines which are dependent on the distance over which the current flows, hereby making the analysis of the read currents more complicated.

Aspects of the present invention have also been realized by a process for providing a non-volatile passive memory device from a passive device memory precursor comprising a support and on at least one side of the support a non-volatile passive memory element precursor, the non-volatile passive memory element precursor comprising on a single surface of the support a first electrode system and a second electrode system together with an insulating system, unless the insulating system is the surface, wherein the first electrode system is insulated from the second electrode system, the first and the second electrode systems are pattern systems and wherein the non-volatile passive memory device is exclusive of metallic silicon and the systems are printable using conventional printing processes with the optional exception of the insulating system if the insulating system is the surface, the process comprising the step of providing at least one conductive or semiconducting bridge between the first electrode pattern and the second electrode pattern at predesignated points. The conductive or semiconducting bridges are substantially parallel with the surface. According to a first embodiment of the process for providing a non-volatile passive memory device from a passive device memory precursor, according to the present invention, the non-volatile passive memory element precursor is coated or conventionally printed with a porous insulating layer. This porous insulating layer enables conductive ink to penetrate through the porous insulating layer to the non-volatile passive memory element.

### Conductive Screen Printing Inks

WO-A 02/079316 discloses an aqueous composition containing a polymer or copolymer of a 3,4-dialkoxythiophene in which the two alkoxy groups may be the same or different or together represent an optionally substituted oxy-alkylene-oxy bridge, a polyanion and a non-Newtonian binder; a method for preparing a conductive layer comprising: applying the above-described aqueous composition to an optionally subbed support, a dielectric layer, a phosphor layer or an optionally transparent conductive coating; and drying the thereby applied aqueous composition; antistatic and electroconductive coatings prepared according to the above-described method for preparing a conductive layer; a printing ink or paste comprising the above-described aqueous composition; and a printing process comprising: providing the above-described printing ink; printing the printing ink on an optionally subbed support, a dielectric layer, a phosphor layer or an optionally transparent conductive coating. The screen printing ink formulations disclosed in WO-A 02/079316 are herein incorporated by reference.

WO-A 03/048228 discloses a method for preparing a composition containing between 0.08 and 3.0% by weight of polymer or copolymer of a 3,4-dialkoxythiophene in which the two alkoxy groups may be the same or different or together represent an optionally substituted oxy-alkylene-oxy bridge, a polyanion and at least one non-aqueous solvent from a dispersion of the polymer or copolymer of (3,4-dialkoxythiophene) and the polyanion in water which is prepared in the substantial absence of oxygen, comprising in the following order the steps of: i) mixing at least one of the non-aqueous solvents with the aqueous dispersion of the polymer or copolymer of (3,4-dialkoxythiophene) and the polyanion; and ii) evaporating water from the mixture prepared in step i) until the content of water therein is reduced by at least 65% by weight; a printing ink, printing paste or coating composition, capable of yielding layers with enhanced conductivity at a given transparency, prepared according to the above-described method; a coating process with the coating composition thereby producing a layer with enhanced conductivity at a given transparency; and a printing process with the printing ink or paste thereby producing a layer with enhanced conductivity at a given transparency. The screen printing ink formulations disclosed in WO-A 03/048228 are specifically incorporated herein by reference. WO-A 03/048229 discloses a method for preparing a composition containing between 0.08 and 3.0% by weight of a polymer or copolymer of a 3,4-dialkoxythiophene in which the two alkoxy groups may be the same or different or together represent a oxy-alkylene-oxy bridge optionally substituted with substituents selected from the group consisting of alkyl, alkoxy, alkyoxyalkyl, carboxy, alkylsulphonato, alkyloxyalkylsulphonato and carboxy ester groups, a polyanion and at least one polyhydroxy non-aqueous solvent from a dispersion of the polymer or copolymer of (3,4-dialkoxythiophene) and the polyanion in water comprising in the following order the steps of: i) mixing at least one of the non-aqueous solvents with the aqueous dispersion of the polymer or copolymer of (3,4-dialkoxythiophene) and the polyanion; and ii) evaporating water from the mixture prepared in step i) until the content of water therein is reduced by at least 65% by weight; a printing ink, printing paste or coating composition, capable of yielding layers with an enhanced transparency at a given surface resistance, prepared according to the above-described method; a coating process with the coating composition thereby producing a layer with enhanced transparency at a given surface resistance; and a printing process with the printing ink or paste thereby producing a layer with enhanced transparency at a given surface resistance. The screen printing ink formulations disclosed in WO-A 03/048229 are specifically incorporated herein by reference.

### Conductive Flexographic Printing Inks

WO-A 03/000765 discloses a non-dye containing flexographic ink containing a polymer or copolymer of a 3,4-dialkoxythiophene in which the two alkoxy groups may be the same or different or together represent an optionally substituted oxy-alkylene-oxy bridge, a polyanion and a latex binder in a solvent or aqueous medium, characterized in that the polymer or copolymer of a 3,4-dialkoxythiophene is present in a concentration of at least 0.1% by weight in the ink and that the ink is capable of producing a calorimetrically additive transparent print; a method of preparing the flexographic ink; and a flexographic printing process therewith. The flexographic printing ink formulations disclosed in WO-A 03/000765 are specifically incorporated herein by reference.

### INDUSTRIAL APPLICATION

The non-volatile passive memory element, according to the present invention, can be used in a wide range of applications by applying it to any entity requiring verification of identity or verification of authenticity e.g. labels, packaging, printed media, identity cards, admission tickets and legal documents.

The non-volatile passive memory devices, according to the present invention, can be used in security and anti-counterfeiting applications e.g. in tickets, labels, tags, an ID-card, a bank card, a legal document, banknotes and packaging and can also be integrated into packaging.

The invention is illustrated hereinafter by way of comparative examples and invention examples. The percentages and ratios given in these examples are by weight unless otherwise indicated.

### Supports Used in the Invention Examples:

SUPPORT 01=a 125 μm thick transparent PET support provided on one side with subbing layer Nr. 01 with the following composition:

| | |
|---|---|
| copolymer of 88% vinylidene chloride, 10% methyl | 79.1 mg/m² |
| acrylate and 2% itaconic acid | |
| Kieselsol ® 100F, a colloidal silica from BAYER | 18.6 mg/m² |
| Mersolat ® H, a surfactant from BAYER | 0.4 mg/m² |
| Ultravon ® W, a surfactant from CIBA-GEIGY | 1.9 mg/m² |

SUPPORT 02=a 125 μm thick transparent PET support; and
SUPPORT 03=a paper support coated on one side with a mixture of 57 wt % of low density polyethylene and 43 wt % high density polyethylene and on the other side with a layer containing 89.5 wt % low density polyethylene and 10.5 wt % titanium dioxide, the titanium dioxide-containing coating being coated to 100 mg/m² with a subbing layer solution with the following composition:

| | |
|---|---|
| deionized water | 67.1 wt % |
| gelatine Z KN 707 from Koepff | 7.0 wt % |
| Saponine Quilaya, 5% in deionized water, | 0.5 wt % |
| from Schmittmann | |
| 2-propanol/butanol/deionized water 36/24/40 | 25.0 wt % |
| Chrome alum, 10% in water | 0.4 wt % |

Ingredients used in non-commercial coatings used in the elements of the INVENTION EXAMPLES:
TANACOTE® FG3, an aqueous carboxylated polypropylene emulsion from SYBRON CHEMICALS;
DYNOL® 604, a non-ionic ethoxylated acetylenic diol surfactant from AIR PRODUCTS AND CHEMICAL INC.;
POLYESTER DISPERSION, is a 25% by weight aqueous dispersion of a polyester of 52.9 mol % terephthalic acid, 40 mol % terephthalic acid, 7 mol % sulfo-isophthalic acid, 0.1 mol % of

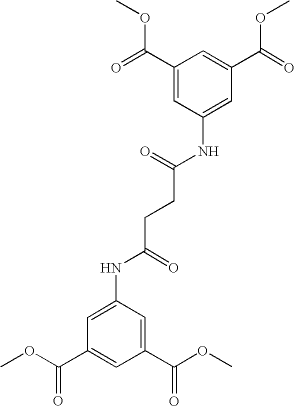

and 100 mol % ethylene glycol.

### Flexographic Ink Used in Invention Examples

The composition of the flexographic ink used in the INVENTION EXAMPLES is given in Table 1 below:

Table 1:

TABLE 1

| Ingredient | Percentage by weight |
|---|---|
| 3.0% by weight dispersion of PEDOT/PSS with | 45.0 |
| a 1:2.4 weight ratio of PEDOT:PSS | |
| deionized water | 14.0 |
| POLYESTER DISPERSION | 5.6 |
| TANCOTE ® FG3 | 1.4 |
| 1,2-propanediol | 1.6 |
| Di(ethylene glycol) methyl ether | 2.9 |
| Di(ethylene glycol) | 4.5 |
| Dibutyl sebacate | 5.0 |
| isopropanol | 20.0 |

### Ink-Jet Ink Used in Invention Examples

The composition of the ink-jet ink used in the INVENTION EXAMPLES is given in Table 2 below:

TABLE 2

| | Percentage by |
|---|---|
| Ingredient | weight |
| 1.1% by weight dispersion of PEDOT/PSS with a | 57.1 |
| 1:2.4 weight ratio of PEDOT:PSS | |
| Deionized water | 28.55 |
| N-methyl pyrrolidone | 14.2 |
| DYNOL ® 604, a non-ionic ethoxylated acetylenic | 0.15 |
| diol surfactant from Air Products and Chemicals | |
| Inc. | |
| N,N-dimethylethanolamine | to adjust pH to 7-8 |

### INVENTION EXAMPLE 1

### Fully Ink-Jet Printed Non-Volatile Passive Memory Device

The first and second electrode systems were ink-jet printed with appropriate electrical contacts for reading out the stored information in contact on the subbed side of SUPPORT 01 from a Universal Printhead (from AGFA-GEVAERT) using the ink-jet ink, the surface of the subbing layer providing the insulating system. A non-volatile passive memory device precursor is thereby provided. Conductive bridges were then provided by ink-jet printing the ink-jet ink from a Universal Printhead (from AGFA-GEVAERT) between predesignated points of the first and the second electrode systems to produce a non-volatile passive memory device.

### INVENTION EXAMPLE 2

### Flexographically/Ink Jet Printed Non-Volatile Passive Memory Device

The first and second electrode systems were printed with appropriate electrical contacts for reading out the stored information in contact by flexographic printing using a Rotary Koater Pilot Press (from R.K. Print Coat Instruments, Ltd.) on SUPPORT 02 using the flexographic ink and then drying in an oven at 109° C. in a roll to roll process, the PET surface providing the insulating system. A non-volatile passive memory device precursor is thereby provided. Conductive bridges were then provided by ink-jet printing the ink-jet ink from a Universal Printhead (from AGFA-GEVAERT) between predesignated points of the first and the second electrode systems to provide a non-volatile passive memory device.

### INVENTION EXAMPLE 3

### Flexographically/Ink Jet Printed Non-Volatile Passive Memory Device

The first and second electrode systems were printed with the appropriate electrical contacts required for reading out the stored information in contact by flexographic printing using a Rotary Koater Pilot Press (from R.K. Print Coat Instruments, Ltd.) on SUPPORT 03 using the flexographic ink and then drying in an oven at 109° C. in a roll to roll process, the surface of the subbing layer providing the insulating system. A non-volatile passive memory device precursor is thereby provided. Conductive bridges were then provided by ink-jet printing the ink-jet ink from a Universal Printhead (from AGFA-GEVAERT) between predesignated points of the first and the second electrode systems to provide a non-volatile passive memory device.

### INVENTION EXAMPLE 4

### Non-Volatile Passive Memory Device Comprising Silver Patterns Via DTR-Technology and Ink Jet Printed Conductive Bridges

### Preparation of a Dispersion of Pds Physical Development Nuclei:

The preparation of the PdS physical development nuclei is described in the example of EP-A 0769 723. From this example solutions A1, B1 and C1 were used to prepare the nuclei in a concentration of 0.0038 mol/L. To 1000 mL of this PdS dispersion 10 g of a 10 g/L water solution of Aerosol™ OT from American Cyanamid and 5 g of a 50 g/L solution of perfluorcaprylamide-polyglycol were added.

### Preparation of the Transfer Emulsion Layer:

The preparation of the silver chlorobromide emulsion and the preparation of the transfer emulsion layer was carried out as disclosed in EP-A 769 723 except that the coverage of silver halide applied was equivalent to 1.25 g/m² of AgNO₃ instead of 2 g/m² thereof.

Production of a non-volatile passive memory device comprising silver patterns via DTR (Diffusion Transfer Reversal)-technology and ink jet printed conductive bridges:

The first and second electrode system patterns of silver were provided using DTR-technology in a four step process on the subbed side of SUPPORT 01 in which: in step 1 the subbed surface of SUPPORT 01 is coated to a gelatine coverage of 35 m²/L with the gelatin solution with the following composition:

| | |
|---|---|
| gelatin | 40 g |
| Hostapon ® T, a surfactant from Clariant | 1 g |
| formaldehyde (4%) | 40 g |
| deionized water to make | 1000 g |

in step 2 the above-described dispersion of PdS physical development nuclei was coated to a wet layer thickness of 13.5 μm on the gelatin layer and then dried for 60 minutes at 25° C., thereby providing a receiver layer;
in step 3 the above-described transfer emulsion layer disclosed was exposed image-wise, the image corresponding to the complementary image of the first and second electrode system patterns; and
in step 4 the exposed transfer emulsion layer was processed in contact with the receiver layer at 25° C. for 10 s with a AGFA-GEVAERT™ CP297 developer solution, thereby producing the first and second electrode system patterns in silver, the surface of the subbing layer providing the insulating system. A non-volatile passive memory device precursor was thereby produced. Conductive bridges were then provided by ink-jet printing the ink-jet ink from a Universal Printhead (from AGFA-GEVAERT) between predesignated points of the first and the second electrode systems to provide a non-volatile passive memory device.

### INVENTION EXAMPLE 5

The non-volatile passive memory device of INVENTION EXAMPLE 2 was coated with the composition given in Table 3 below using a 100 μm wirebar, ensuring that the electrical contacts for reading out the stored information in contact were masked, giving an opaque macroporous layer after drying at 50° C.

TABLE 3

| | weight |
|---|---|
| Ingredient | [g] |
| Syloid ™ W300, a colloidal silica from GRACE GMBH | 75.6 |
| Poval PVA R3109, a silanol modified polyvinyl alcohol from | 2.3 |
| KURARAY CO. | |
| Catfloc ™ T2, a cationic polyelectrolyte from CALGON | 5.6 |
| EUROPE | |
| Bronidox ™ K, a biocide from HENKEL (5% solution | 0.3 |
| in ethanol) | |
| Citric acid | 0.3 |
| Polysol ™ EVA P-550, a 50% aqueous emulsion of an ethylene- | 100 |
| vinyl acetate-vinyl versatate copolymer from SHOWA HIGH | |
| POLYMER CO. | |
| Aerosol ™ OT, a surfactant from CYTEC | 1.5 |
| Tergitol ™ 4, a surfactant from UNION CARBIDE | 1.0 |
| Water to make | 1000 |

### INVENTION EXAMPLE 6

A UV curable transparent lacquer with the composition given in Table 4 was applied with a 50 μm wirebar to the macroporous opaque layer of the non-volatile passive memory device of INVENTION EXAMPLE 5.

TABLE 4

| | weight |
|---|---|
| Ingredient | [g] |
| Isobornylacrylate | 416.2 |
| Actilane ™ 411, a monofunctional acrylate diluent from AKZO | 247.7 |
| NOBEL | |
| Ebecryl ™ 1039, an urethanemonoacrylate from UCB | 178.4 |
| CHEMICALS | |
| Ebecryl ™ 11, a polyethylene glycol diacrylate from UCB | 99.1 |
| CHEMICALS | |
| Irgacure ™ 500, a photo-initiator from CIBA-GEIGY | 49.6 |
| Perenol ™ S Konz (50% in ethyl acetate), a surfactant from | 9.0 |
| HENKEL | |

About two minutes after the application of the transparent lacquer, curing was performed with a DRSE-120 conveyor with VPS/1600 UV lamp (speed 20 m/min, 50% UV power setting). Complete curing required three passes. Due to the complete penetration of the UV lacquer into the macroporous layer, the macroporous layer became totally transparent so that the underlying electrode systems became clearly visible.

The present invention may include any feature or combination of features disclosed herein either implicitly or explicitly or any generalisation thereof irrespective of whether it relates to the presently claimed invention. In view of the foregoing description it will be evident to a person skilled in the art that various modifications may be made within the scope of the invention.

1. A non-volatile passive memory element comprising on a single surface a first electrode system and a second electrode system together with an insulating system, unless said insulating system is said surface, wherein said first electrode system is insulated from said second electrode system, said first and said second electrode systems are pattern systems and at least one conductive or semiconducting bridge is present between said first and said second electrode systems, and wherein said non-volatile passive memory device is exclusive of metallic silicon and said systems and said conductive or semiconducting bridges are printable using conventional printing processes with the optional exception of said insulating system if said insulating system is said surface.

2. The non-volatile passive memory element according to claim 1, wherein said non-volatile passive memory element comprises a series of interrupted conducting or semiconducting lines bridged by at least one conductive or semiconducting bridge.

3. The non-volatile passive memory device comprising a support and on at least one side of said support a non-volatile passive memory element according to claim 1.

4. The non-volatile passive memory device according to claim 3, wherein at least one of said first and second patterned electrode systems comprises an inorganic conducting medium or an organic conducting medium.

5. The non-volatile passive memory device according to claim 3, wherein said at least one conductive or semiconducting bridge comprises an inorganic conducting medium or an organic conducting medium.

6. The non-volatile passive memory device according to claim 4, wherein said organic conducting medium is an intrinsically conductive organic polymer.

7. The non-volatile passive memory device according to claim 6, wherein said intrinsically conductive organic polymer is a polythiophene, a polyaniline or a polypyrrole.

8. The non-volatile passive memory device according to claim 6, wherein said polythiophene is a poly(3,4-alkylenedioxythiophene).

9. The non-volatile passive memory device according to claim 6, wherein said polythiophene is poly(3,4-ethylenedioxy-thiophene).

10. The non-volatile passive memory device according to claim 3, wherein at least one of said first patterned electrode system, said second patterned electrode system, said insulating system and said at least one conductive or semiconducting bridge is transparent.

11. The non-volatile passive memory device according to claim 3, wherein said non-volatile passive memory device is transparent.

12. The non-volatile passive memory device according to claim 3, wherein said conductive or semiconducting bridges are coloured.

13. The non-volatile passive memory device according to claim 3, wherein said non-volatile passive memory device is overprinted with an image or a homogeneously colored or opaque layer visually to hide the location of said conductive or semiconducting bridges except for any electrical contacts required for reading out the stored information in contact.

14. The non-volatile passive memory device according to claim 3, wherein a colored or opaque foil is laminated over said passive device to visually hide the location of said conductive or semiconducting bridges except for any electrical contacts required for reading out the stored information in contact.

15. A process for preparing a non-volatile passive memory device according to claim 3, comprising the realization on a single surface of said support of the steps of: providing a first electrode system pattern, optionally providing an insulating pattern, providing a second electrode system pattern, and providing at least one conductive or semiconducting bridge between the first electrode system pattern and the second electrode system pattern at predesignated points, wherein at least one of the steps is realized with a conventional printing process and two of said steps are optionally performed simultaneously.

16. The process according to claim 15, wherein said provision of said second patterned electrode is realized in the same process step as said at least one conductive or semiconducting bridge between said first patterned electrode system and said second patterned electrode system.

17. The process according to claim 15, wherein at least one of said at least one conventional printing processes is a non-impact printing process.

18. The process according to claim 15, wherein at least one of said at least one conventional printing processes is an impact printing process.

19. The process according to claim 15, wherein said at least one conventional printing process is selected from the group consisting of ink-jet printing, intaglio printing, screen printing, flexographic printing, offset printing, stamp printing, gravure printing and thermal and laser-induced processes.

20. The process according to any one of claims 15 to 19, wherein in a further step one or more of said at least one conductive or semiconducting bridge on pre-selected points between said first electrode pattern and said second electrode pattern are rendered inoperative.

21. The process according to claim 15, wherein in a further step said non-volatile passive memory element is coated with an insulating layer except for any electrical contacts required for reading out the stored information in contact.

22. The process according to claim 21, wherein said insulating layer is opaque.

23. The process according to claim 22, wherein said opaque insulating layer is porous.

24. The process according to claim 22, wherein said insulating layer is capable of being rendered integrally or locally transparent in a further process step.

25. A non-volatile passive memory device precursor comprising a support and on at least one side of the support a non-volatile passive memory element precursor, said non-volatile passive memory element precursor comprising on a single surface of said support a first electrode system and a second electrode system together with an insulating system, unless said insulating system is said surface, wherein the first electrode system is insulated from the second electrode system, said first and said second electrode systems are pattern systems and wherein the non-volatile passive memory device is exclusive of metallic silicon and said systems are printable using conventional printing processes with the optional exception of said insulating system if said insulating system is said surface.

26. The non-volatile passive memory device precursor according to claim 25, wherein said non-volatile passive memory element precursor is coated or printed with a porous insulating layer.

27. A process for providing a non-volatile passive memory device from a passive device memory precursor comprising a support and on at least one side of the support a non-volatile passive memory element precursor, said non-volatile passive memory element precursor comprising on a single surface of said support a first electrode system and a second electrode system together with an insulating system, unless said insulating system is said surface, wherein the first electrode system is insulated from the second electrode system, said first and said second electrode systems are pattern systems and wherein the non-volatile passive memory device is exclusive of metallic silicon and said systems are printable using conventional printing processes with the optional exception of said insulating system if said insulating system is said surface, said process comprising the step of providing at least one conductive or semiconducting bridge between the first electrode pattern and the second electrode pattern at predesignated points.

28. The process for providing a non-volatile passive memory device from a passive device memory precursor according to claim 27, wherein said non-volatile passive memory element precursor is coated or printed with a porous insulating layer.
